(19) United States
(12) Patent Application Publication
(10) Pub. No.: US 2025/0279626 A1
(43) Pub. Date: Sep. 4, 2025

(54) MANAGING IMPEDANCE MISMATCHES FOR ELECTRO-ABSORPTION MODULATED LASERS

(71) Applicant: MELLANOX TECHNOLOGIES, LTD., Yokneam (IL)

(72) Inventors: Uziel Koren, Herzliya (IL); Oren Steinberg, Tal Shahar (IL); Moshe Oron, Rehovot (IL); Isabelle Cestier, Haifa (IL); Elad Mentovich, Tel Aviv (IL); Timothy De Keulenaer, Ghent (BE); Jochem Verbist, Edegem (BE)

(21) Appl. No.: 18/591,749

(22) Filed: Feb. 29, 2024

(51) Int. Cl. H01S 5/042; H01S 5/00; H01S 5/0233

(52) U.S. Cl. CPC H01S 5/0427; H01S 5/0078; H01S 5/0085; H01S 5/0233

(57) ABSTRACT

Approaches presented herein provide for the reduction of unwanted electrical reflections caused by impedance mismatches at an input of an optical modulator device, such as at the interface between a (radio frequency) signal source and an electro-absorption modulated laser (EML). Reflections can be reduced though use of one or more electrical filters, such as resistor-capacitor (RC) filters, that can be placed at the input of the EML device to reduce reflections through impedance matching at that location, while maintaining the efficiency and bandwidth of the modulator for high bandwidth transmission. Such a filter can be used with a single ended or differential EML device, and can be integrated on an EML chip or added as discrete components on a chip carrier on which the EML chip is supported.

### TECHNICAL FIELD

This disclosure relates to transmission of data using electrical and optical signals, including conversion between types of signals for a given transmission.

### BACKGROUND

In various optical-based approaches to telecommunications or data transmission, binary data is encoded into an optical signal for propagation over an optical fiber. A laser can be used to provide a continuous source of light, and an optical modulator can be used to swiftly adjust and modulate the amplitude of the laser beam, or other such aspect, in order to encode the data, effectively converting an input electrical signal to an optical signal for optical transmission. An electro-absorption modulator (EAM) can be used for such purposes, which can operate at relatively low voltage and at very high speed. An issue that can be experienced with such an electro-absorption modulated laser (EML) device is that there will often be a mismatch between the impedances of an electrical signal source and the electro-absorption modulator (EAM). This mismatch may occur due to changes in the operating conditions, such as temperature, or the need to increase bandwidth. Such a mismatch may reduce the modulator efficiency or cause unwanted electrical reflections into the signal source, which may degrade the integrity of the transmitted optical signal.

### BRIEF DESCRIPTION OF THE DRAWINGS

Various embodiments in accordance with the present disclosure will be described with reference to the drawings, in which:

FIG. 1 illustrates a perspective view of an example EML device including electrical filters, according to at least one embodiment;

FIG. 2 illustrates example single-ended EAM circuits with an electrical filter, according to at least one embodiment.

FIG. 3 illustrates example differential EAM circuits with integrated electrical filters, according to at least one embodiment.

FIG. 4 illustrates performance parameters for EML devices with, and without, integrated electrical filters, according to at least one embodiment.

FIG. 5 illustrates an example data transmission pipeline, according to at least one embodiment;

FIG. 6 illustrates an example process that can be performed to reduce impedance mismatches in an EML device, according to at least one embodiment;

FIG. 7 illustrates components of a distributed system in which an EML device can be used, according to at least one embodiment;

FIG. 8 illustrates an example data center system, according to at least one embodiment;

FIG. 9 is a block diagram illustrating a computer system, according to at least one embodiment;

FIG. 10 is a block diagram illustrating a computer system, according to at least one embodiment;

FIG. 11 illustrates a computer system, according to at least one embodiment;

FIG. 12 illustrates a computer system, according to at least one embodiment;

FIG. 13 illustrates exemplary integrated circuits and associated graphics processors, according to at least one embodiment;

FIGS. 14A, 14B illustrate exemplary integrated circuits and associated graphics processors, according to at least one embodiment;

FIG. 15 illustrates a computer system, according to at least one embodiment;

FIG. 16A illustrates a parallel processor, according to at least one embodiment;

FIG. 16B illustrates a partition unit, according to at least one embodiment;

FIG. 17 illustrates at least portions of a graphics processor, according to one or more embodiments.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

The systems and methods described herein may be used by, without limitation, non-autonomous vehicles or machines, semi-autonomous or autonomous vehicles or machines (e.g., in one or more advanced driver assistance systems (ADAS), one or more in-vehicle infotainment systems, one or more emergency vehicle detection systems), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, generative AI, model training or updating, perception, augmented reality, virtual reality, mixed reality, robotics, security and surveillance, simulation and digital twinning, autonomous or semi-autonomous machine applications, deep learning, environment simulation, data center processing, conversational AI, light transport simulation (e.g., ray-tracing, path tracing, etc.), collaborative content creation for 3D assets, generative AI, cloud computing, and/or any other suitable applications.

Disclosed embodiments may be comprised in a variety of different systems such as automotive systems (e.g., an in-vehicle infotainment system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models—such as large language models (LLMs), systems for performing generative AI operations (e.g., using one or more language models), systems for performing light transport simulation, systems for performing collaborative content creation for 3D assets, systems implemented at least partially using cloud computing resources, and/or other types of systems.

Approaches in accordance with various illustrative embodiments provide for the reduction of unwanted electrical reflections caused by impedance mismatches at an input of an optical modulator device, such as at the interface between a (radio frequency) signal source and an electro-absorption modulated laser (EML). Such reflections can degrade signal integrity, which can impact the quality of data transfer for telecommunications, data center, or other such transmissions by causing distortion to signal source operation. These reflections can be reduced though use of one or more electrical filters, such as resistor-capacitor (RC) filters with at least one resistor and capacitor in parallel. An RC filter can be placed at the input of the EML device to reduce reflections through impedance matching at that location, while maintaining the efficiency and bandwidth of the modulator for high bandwidth transmission. Such a filter can be used with a single ended or differential EML device, among other such options. The filter can be integrated on an EML chip or added as discrete components on a chip carrier on which the EML chip is mounted. In at least one embodiment, filter integration can be achieved using thin metals and dielectric layers that are commonly employed in the EML manufacturing process.

Variations of this and other such functionality can be used as well within the scope of the various embodiments as would be apparent to one of ordinary skill in the art in light of the teachings and suggestions contained herein.

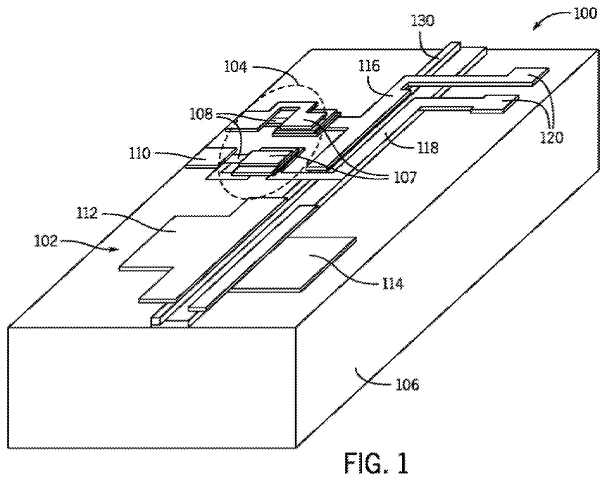

FIG. 1 illustrates a perspective view of an example differential electro-absorption modulated laser (EML) device 100, according to at least one embodiment. Such a device can receive an electrical signal and convert that electrical signal to an optical signal for transmission over an optical fiber. In this example, the EML device 100 includes an distributed-feedback (DFB) laser 102, although other types of laser diodes or continuous wave laser devices can be used as well within the scope of the various embodiments. The resonator of a DFB can consist of an active region containing a periodically structured element, which provides optical feedback to the laser. The EML optical waveguide 130 can cause light (e.g., continuous wave light) from the DFB laser 102 to be directed to an EAM 108. In this example, the EAM 108 can be a semiconductor device that is positioned on the same semiconductor chip substrate 106 as the DFB laser 102. The substrate 106 can be at least one of the semiconductor materials such as Indium Phosphide (InP), Gallium Arsenide (GaAs), or silicon (Si). In this example, the substrate 106 is a semi-insulating indium phosphide (InP) substrate, as may be formed from an InP wafer of appropriate size for telecommunications applications. In this example the EAM 108 is a differential EAM. It can be configured to modulate the intensity of the laser beam based on a differential electrical signal from a differential signal source, which may be external to the EML device 100. A modulator can act like a shutter, which can allow or disallow light from the continuous wave laser to pass at any time, in order to effectively transmit binary data through the amplitude, intensity, or phase of the light over a period of time using levels representing bit values of 1 or 0 in at least one embodiment. In other embodiments the modulator can adjust the amplitude level of the transmitted light wave, such as for example, by using pulsed amplitude modulation (PAM) modulation formats. As illustrated, the laser can include an anode contact 112 and a cathode contact 114, and the EAM can include an EAM anode 116 and an EAM cathode 118, along with EAM output pads 120 to a termination resistor, which can all be formed out of the same metal layer stack, such as for example Titanium-Platinum-Gold metal stack which is common in the industry.

As mentioned, there can be differences in impedance between various devices, such as in impedance between an electrical signal source and an EAM 108. These differences in impedance can lead to issues such as the generation of RF reflections. The magnitude of the impedance mismatch can have a corresponding increase in the magnitude of the RF reflections, as described in more detail later herein. The reflections can be measured as a function of frequency, in at least one example using small signal parameters, such as S11 which corresponds to the input reflection coefficient with the output terminated by a termination load, S21 which corresponds to a forward transmission, and S22 which corresponds to an output reflection coefficient. Among other such options, these parameters can be used to measure the performance of the device.

As illustrated in FIG. 1, the example EML device 100 includes at least one electrical filter 104, such as a resistor-capacitor (RC) filter. An RC filter can include at least one resistor 108 and at least one capacitor 107, arranged in parallel or another such configuration, but other types of electrical filters may be used as well within the scope of the various embodiments, as may include inductors or other such electrical components. The RC input filters 104 can be monolithically integrated on the same chip as the laser and EAM, or comprised of discrete components on a chip carrier supporting the semiconductor chip, among other such options. One or more electrical filters can be added at the input of the EML device in order to reduce electrical reflections from the EML device, as well as to increase the bandwidth or flatten the frequency response of the device, among other such options. The reduction in electrical reflections can be achieved without compromising the efficiency and bandwidth product of the modulator. Although illustrated for a differential EML device, such a filter can be used advantageously with a single ended EML or other such device as well. A single-ended device functions as a transmission mechanism including a single live data rail and a ground or reference region. A differential device functions as a transmission mechanism that has two live data rails and a surrounding ground or reference region, with the signal being determinable between the two live rails that are in opposite phases.

As mentioned, such a device is often used to direct optical signals through optical fibers for large telecommunication network or data centers, where a massive amount of data needs to be transferred quickly, accurately, and securely. As the need for large amount of data processing increases, so does the demand for high data rate interconnects at low cost and low power consumption. As an example, forthcoming optical links require optical modulators capable of operating with high bandwidth (BW) in the range of 60-150 GHz. An InP-based electro-absorption modulated laser optical device such as that illustrated in FIG. 1 can be used for such high-speed optical transmission, with InP-based electro-absorption modulators being able to achieve the required bandwidth while being monolithically integrated on the same chip with the semiconductor laser continuous wave (CW) light source. Such an EML can be very compact, and can have inherently lower coupling loss, lower power consumption, and lower cost compared to other high bandwidth hybrid solutions. These types of EMLs can be used advantageously for optical links in large data centers, where these attributes can be of particular relevance.

An electro-optical modulator can be used in such devices to convert electrical signals into optical signals that are to be transmitted through optical fibers and then converted back into electrical signals at the destination. In data centers, often high bit rate electrical radio frequency (RF) signals are generated and received by serializer-deserializer (SerDes) integrated circuits. In various implementations, a SerDes transmitter may have a differential electrical RF output port, followed by an RF driver which feeds the electrical signal into a single-ended electro-optic EAM. In at least some embodiments, a SerDes may be connected directly to a differential EAM without an intermediate driver. A SerDes might be associated with a data service, for example, that can communicate with different points in a data center, for example, in order to transmit data as needed throughout the data center (as well as outside the data center). A data service can provide parallel data signals to a component such as a SerDes device, which can provided the RF electrical signal to the modulator.

One or more RC input filters 104 can be used to improve the RF matching between an EAM device and an external RF signal source (not illustrated in FIG. 1), where the electrical signal from the source can be connected to the EAM input pads 110. Good impedance matching can be important, in at least some embodiments, for efficient RF connection between high frequency electrical devices. When the source and load impedances are not sufficiently matched, unwanted reflected electrical waves can be formed that may reduce the efficiency of the electrical transmission and may cause distortion to the signal source operation. The amplitude of the reflected electrical wave can be given by the reflection coefficient γ, where:

$$γ = \frac{{z}_{o} + {z}_{1}}{{z}_{o} + {z}_{1}}$$

where z₀ and z₁ are the complex impedances of the source and load, respectively. The reflected power return loss, in logarithmic scale, can be characterized over frequency by the small signal parameter S11 as a function of frequency, where:

$$S 11 = - 20 log ( \vert γ \vert )$$

The transmitted wave fraction over frequency is measured by the small signal parameter S21, and the frequency at which it drops by 3 dB is known as the 3 dB bandwidth of the device.

While InP based EMLs in the previous art are typically single-ended devices, differential EAM devices can also be used as mentioned previously utilizing silicon photonics technology. Differential EMLs can be beneficial in use for applications such as data center operations, as differential RF signaling is often being employed by the SerDes. This is due in part to the numerous advantages of differential drive signaling, such as double signal voltage, common mode and supply noise rejection, better cross talk immunity, and potential for higher bandwidth.

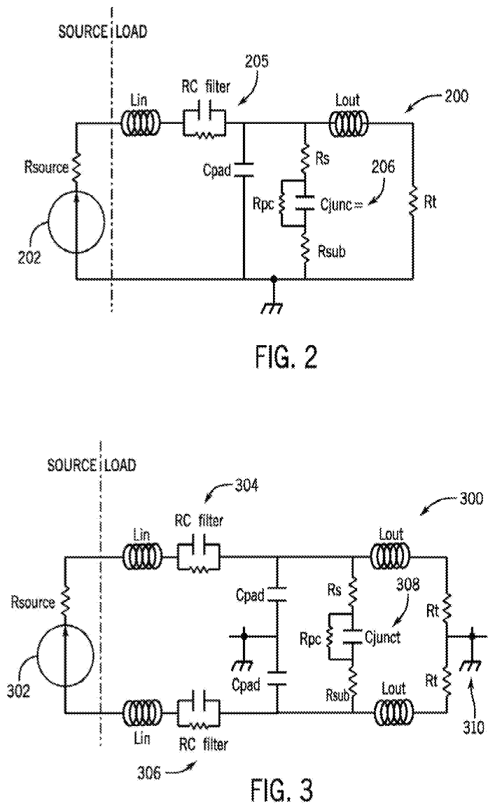

FIG. 2 illustrates a schematic equivalent circuit 200 of a single ended EAM that can be used according to at least one embodiment. The load device (e.g., the EAM) can be represented by a small signal equivalent circuit which contains the inherent EAM junction capacitance C_{junc}, series resistance Rₛ, and parallel resistance of the EAM p-n junction R_{pc}, as well as outside elements in the chip and in the package, such as bond wires inductance Lᵢₙ Lₒᵤₜ, pads capacitance C_{pad}, and termination resistor Rₜ. The signal source is represented by a signal generator 202 and a resistive source impedance Rs. As mentioned, an RC filter 205 is inserted in the input line to reduce the impedance mismatch between the source device and the load (EAM) device.

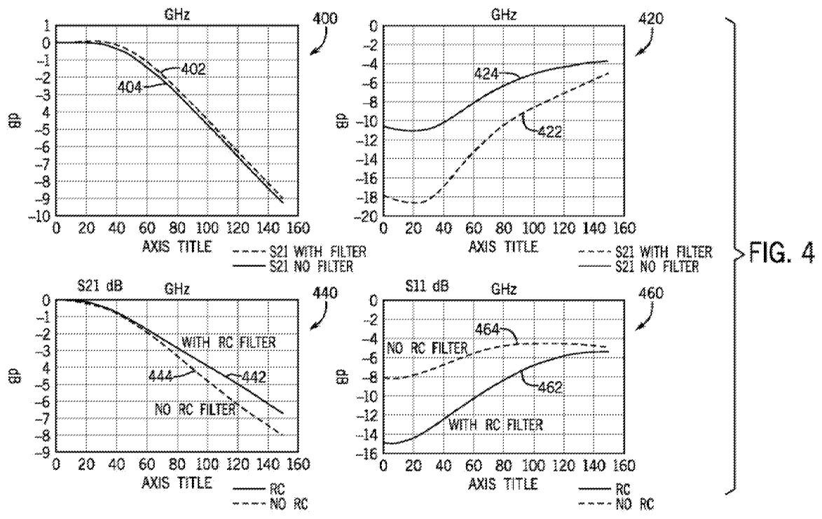

FIG. 3 illustrates a schematic equivalent circuit 300 of a differential EAM that can be used according to at least one embodiment. In FIG. 3, a source 302 of electrical signal with source impedance R_{source} is provided to the circuit. The circuit is shown to include various resistors, capacitor, and inductors, as well as a ground or reference connection 310, the selection, number, and placement of which may vary between embodiments. The circuit 300 also includes an optical modulator 308 that can operate according to the input electrical signal. The differential circuit 300 of FIG. 3 also includes an electrical source input 302 and an optical modulator 308 with a differential arrangement of electrical components. The RC filters 304 and 306 are inserted into the two differential input rails of the EAM 308 in order to improve the impedance matching between the source and load devices.

As mentioned, impedance mismatches between the electrical source and the optical modulator can lead to RF reflections. The small signal S parameters can be calculated for such a circuit as a measure of performance as relates to the presence of such reflections. Small signal analysis can illustrate design conflicts and tradeoffs regarding the overall performance of an EAM. Specifically, the dynamic extinction ratio (ER) per unit drive voltage (also known as the modulation efficiency) can depend on the modulator length Lₑₐₘ. However, increasing Lₑₐₘ can also increase the modulator capacitance and reduce bandwidth, because the frequency response can be limited by the characteristic RC cutoff frequency, as may be given by:

$${f}_{c} = \frac{1}{2 π RC}$$

Another potential tradeoff can relate to the conflict between the bandwidth and the reflection return loss parameter S11. To increase bandwidth, for example, the termination resistance can be reduced slightly below that of the source resistance, and the output inductance Lₒᵤₜ increased. Such an approach may however result in an increase in the impedance mismatch and may result in unacceptably high return loss over the operational bandwidth of the device. The source resistance R_{source} of the device for single ended signal source as illustrated in FIG. 2 can be in the range of around 40-50Ω (ohms), and about twice as high in the range of around 80-100Ω (ohms) for a differential EAM as illustrated in FIG. 3, with the modulator capacitance C_{junc} being mostly unchanged. In other embodiments, other ranges may be used. Tradeoffs needed to obtain the high bandwidth and low reflections, particularly for next generation devices, can become more difficult for the differential EAM case, and the use of the RC filters in the differential EAM case may be particularly important to mitigate some of these constrains.

A traveling wave EAM (or differential traveling wave EAM) may also be used in at least one embodiment. In a traveling wave EAM, the electrodes can be composed of one or several segments separated by passive optical waveguide sections, and connected as discreet loads on an RF transmission line. A traveling wave EAM can allow for increased bandwidth and modulation efficiency in at least some instances. A differential traveling wave EAM may suffer from similar conflicts and tradeoffs between bandwidth, electrical reflections, and modulation efficiency. Approaches in accordance with various embodiments can help to mitigate these conflicts by adding additional elements—such as RC filters—at the input of the EML device, so the value of parameter S11 can be reduced, without significantly degrading the bandwidth and modulation efficiency product of the device.

In at least one embodiment, a high pass filter can be used that attenuates the signal by about 0.8 dB at low frequencies and passes the signal at high frequencies. The filter attenuation can drop by about a factor of 2 at the filter characteristic frequency f_{c}, as given above. By introducing similar filters at the input of an EAM device, with f_{c} near the bandwidth of the EAM, there can be some amount of reduction in the modulation efficiency, but an increase in bandwidth. In addition, there can be a marked reduction of the reflection coefficient and improvement in the S11 response. FIG. 2 illustrates an equivalent circuit 200 for a single ended modulator with an RC filter 205, in accordance with at least one embodiment. As illustrated, the RC filter 205 is positioned on the load side of the circuit, between the electrical source input 202 and the optical modulator 206 on the “live” data side of the circuit. FIG. 3 illustrates an equivalent circuit 350 for differential modulators with a pair of RC filters 352, 354 according to at least one embodiment. As illustrated, there is one RC filter positioned along each live data lines between the electrical input source 252 and the optical modulator 254. As mentioned elsewhere herein, other circuits can be used as well, that may have different numbers, types, and selections of electrical components (e.g., resistors, capacitors, inductors, and the like) in accordance with various embodiments. The electrical filters can contain electrical components of any appropriate material, such as Nickel Chrome (NiCr) for the resistors and Silicon Nitride (SiN) for the capacitor dielectric layers, which are common in the industry. It may also contain other materials such as carbon particles and non-conductive ceramics for resistors, and ceramic materials between insulating dielectrics for capacitors. An RC filter can be designed to function as a type of high pass filter with different attenuations at different frequencies.

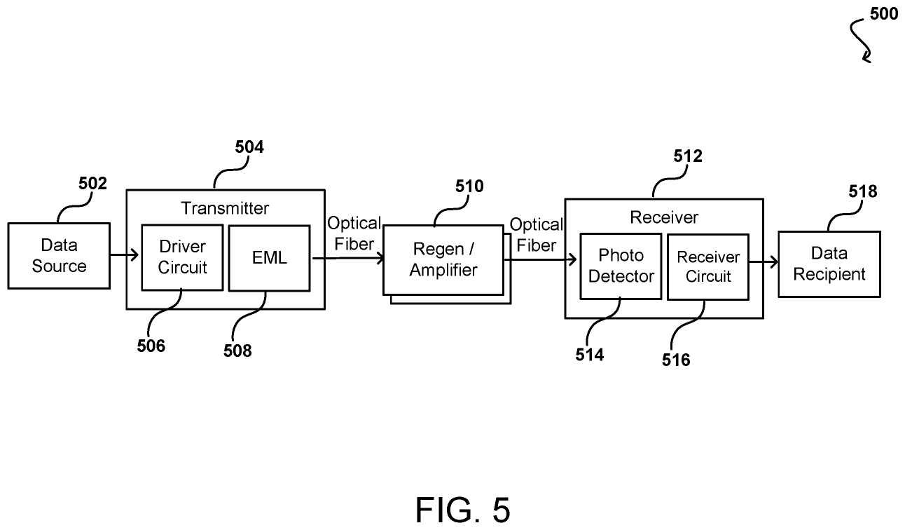

As mentioned, such input RC filters can be implemented on a chip carrier in at least one embodiment, while in another embodiment such RC filters can be integrated on an EML chip. In either case, it can be beneficial to position the filter(s) close to the optical modulator in order to avoid issues resulting from the inductance of wires as the length of the wires increases. If the capacitances are in the range of about 100-350 fF (femtofarads), and resistances are in the range of 8-15Ω (ohms), for example, such filter integration can be achieved using thin metals and dielectric layers that are commonly employed in the EML manufacturing process. The small values of the capacitors and resistors in these filters can allow for implementation on a relatively small area of the chip. The use of common layers of material is illustrated in FIG. 1. The improvement in performance for EML devices with integrated input RC filters has been observed using electromagnetic numerical simulation software, producing an increase in bandwidth and reduced S11 return loss. Improvement in bandwidth and S11 can also be observed for differential traveling wave EAMs (TWEAMs). The high bandwidth obtained with the differential TWEAM with a total modulator length of 102 um is available with high modulation efficiency due to the increased active length of the device compared with the previous examples shown above, and also due to the high voltage swing available to differential modulators. Simulation results shown in FIG. 4 demonstrate the benefits of the input RC filters of this invention for obtaining high BW and reduced return loss that are useful for the differential TWEAM devices.

As mentioned, a benefit of using such EML devices is that they may achieve higher performance at low power. Many of these devices will be deployed in environments such as network data centers supporting Internet and other such traffic, which may include buildings having multiple servers that may all run at, or near, capacity over much of a given day. Not only do these servers have significant power requirements during such operation, but these servers can generate a significant amount of heat that requires cooling, further increasing the power needs, in addition to lighting and other operational power needs. It can therefore be advantageous to implement components or approaches that require relatively little power, in order to reduce cost an improve efficiency. An EML device with an RC filter as discussed herein can provide for low power consumption and cost, while supporting high bandwidths such as 100 GHz or higher. Part of the low cost comes from the fact that EAMs can be built using small semiconductor chips that contain a very small semiconductor laser and a very small modulator that are coupled together optically. Because the laser is incorporated into the chip, there is no need to align a separate laser component and ensure that the laser does not fall out of alignment over time. Such small, integrated components can also be very low loss, and in many instances do not require cooling, such as with a thermoelectric cooler.

FIG. 4 illustrates example electromagnetic simulation results for circuits with, and without, the use of one or more electrical filters. A first plot 400 illustrates the S21 parameters with an electrical filter 402 and without an electrical filter 404, with a noticeable shift in overall performance for a single ended EAM. A second plot 420 illustrates the S11 parameters with 422 and without 424 an electrical filter for a single EAM, where a significant different in performance is observed. For a differential EAM, a third plot 440 illustrates the S21 parameter values with 442 and without 444 electrical filters. Similarly, a fourth plot 460 illustrates the S11 parameters for a differential EAM with 462 and without electrical filters. In each instance, there is a noticeable improvement in performance with use of one or more electrical filters as discussed herein.

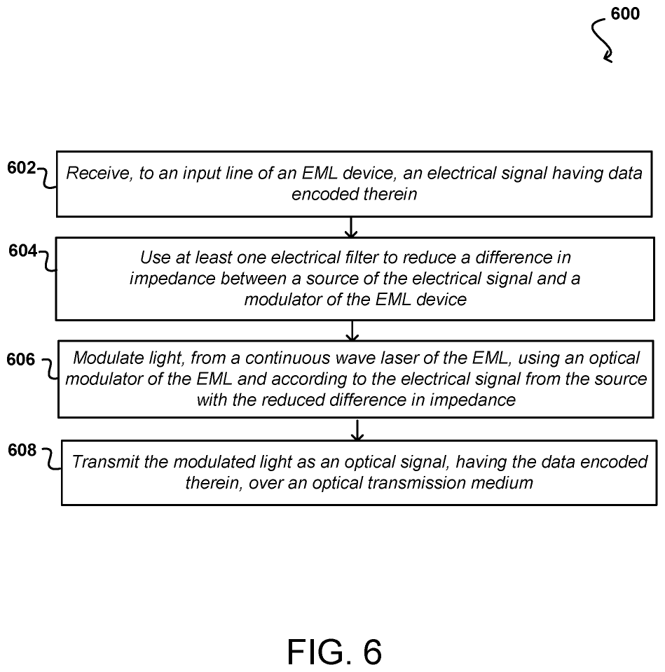

FIG. 5 illustrates an example data transmission pipeline 500 in which aspects of various embodiments can be implemented. This example illustrates transmission in a single direction for simplicity but it should be understood that there could be bidirectional communications between the data source 502 and the data recipient 518, or other such entities, using at least some of these and other such components within the scope of the various embodiments. In this example, a data source 502 provides data that is to be transmitted to a recipient 518. The source can be any appropriate source, such as a client, application, process, device, data server, and the like. The data can be provided to a transmitter 504, which can include a driver circuit 506 and an EML device 508 as discussed herein. The EML device 508 can include an EAM to convert the electrical signal from the data source 502 to an optical signal that can be transmitted over an optical fiber or other such transmission mechanism. As mentioned, the EML device 508 can include at least one electrical filter to reduce an impedance mismatch between the source of the electrical signal and the EAM of the EML device 508. During transmission, the optical signal may pass through one or more components, such as one or more signal regeneration or amplification devices 510, as well as routers, switches, and the like. The optical signal may be received to a receiver 512, which can include a photo detector 514 or similar device for detecting the optical signal and converting the optical signal to an electric signal, as well as a receiver circuit 516 for taking the electrical signal and providing the electrical signal, including the encoded data, to the data recipient 518. It should be understood that there can be various other components to such a pipeline as well, which can include many different data paths or options, within the scope of the various embodiments.

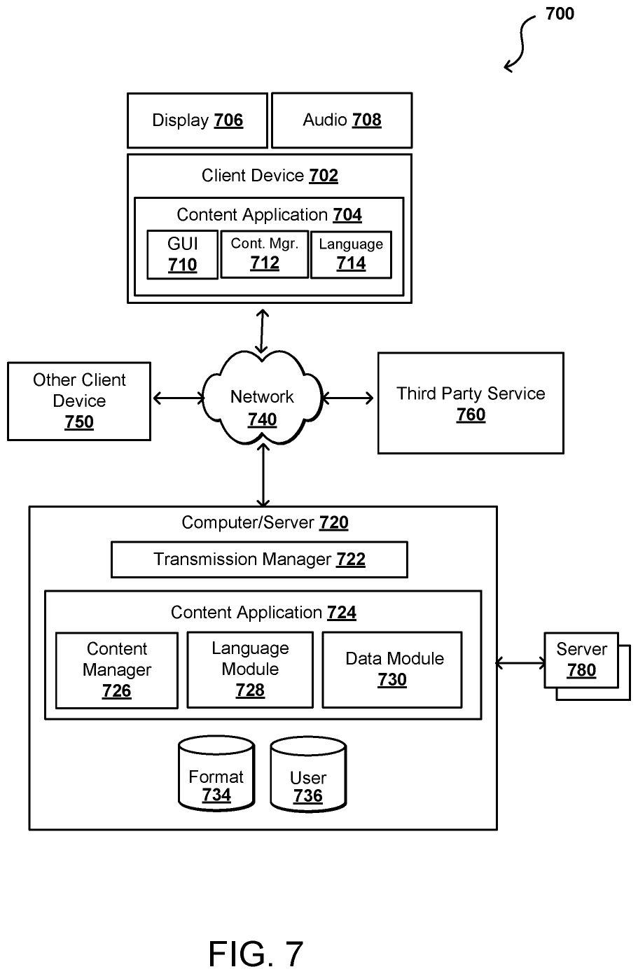

FIG. 6 illustrates an example process 600 that can be performed to reduce impedance mismatch in an EML device, in accordance with at least one embodiment. It should be understood that for this and other processes discussed herein that there may be additional, fewer, or alternative steps performed in similar or alternative orders, or at least partially in parallel, within the scope of the various embodiments. Further, although discussed with respect to an EML device including an EAM, it should be understood that advantages of using one or more electrical filters to improve performance can be used with other types of communications, signal conversion, and/or transmission devices as well within the scope of the various embodiments. In this example process, an electrical signal is received 602 to an input line of an EML device, where the electrical signal has data encoded therein. At least one electrical filter of the EML device can be used 604 to reduce a difference in impedance between the source of the electrical signal and a modulator, such as an EAM, of the EML device. Light from a continuous wave laser (or other such source) of the EML can be modulated 606 using an optical modulator (e.g., an EAM) of the EML device, according to the electrical signal from the source with the reduced difference in impedance. The modulated light can then be transmitted 608 as an optical signal, having the data encoded therein, over at least one optical transmission mechanism. As mentioned, such a process can be performed by any of a set of different transmission devices, such as may be located in a data center or other such location and can offer high bandwidth and performance with low power and at low cost, with minimal data impact due to RF reflections resulting from impedance mismatches.

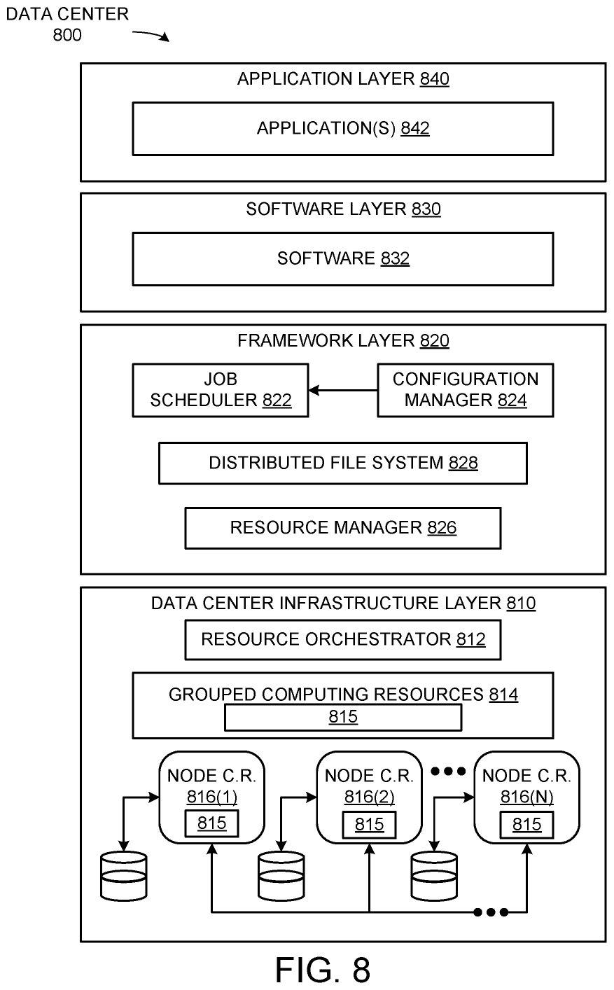

As an example, FIG. 7 illustrates an example network configuration 700 that can be used to provide, generate, modify, encode, process, fuse, and/or transmit data or content between various devices. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a computer, vehicle, or robot), as may use a session manager and user data stored in a user database 736, and can any data to be formatted according to format information stored in a format repository 734. A content manager 726 of a content application 726 may generate, update, modify, or reformat content or data to be transmitted, as may involve a language module 728, data module 730, or other such component. At least a portion of the content or data can be transmitted to the client device 702 using an appropriate transmission manager 722 to send by download, streaming, or another such transmission channel. An encoder may be used to encode and/or compress at least some of this data before transmitting to the client device 702. Further, a device such as an EML device can be used to convert the data encoded into an electrical signal into data encoded in an optical signal that can be transmitted using one or more optical fibers (or other such optical media) of the transmission network(s) 740. In at least one embodiment, a client device 702 receiving such content can provide this content to a corresponding content application 704, which may also or alternatively include a graphical user interface 710 and content manager 712 for use in providing, synthesizing, rendering, compositing, modifying, or using content for presentation, navigation, control, (or other purposes) on or by the client device 702. The content application 704 can also include a language module 714 that can perform various tasks, such as may relate to translating or reformatting received data. In some embodiments, the computer/processor 720 and client device 702 may be able to communicate directly without needing to transmit data over at least one network 740, in order to avoid issues with latency and availability, etc. A decoder may also be used to decode data received over the network 740 for presentation via client device 702, such as map content through a display device 706 and audio, such as sounds and music, through at least one audio playback device 708, such as speakers or headphones. In at least one embodiment, at least some of this content may already be stored on, rendered on, or accessible to client device 702 such that transmission over network 740 is not required for at least that portion of content, such as where that content (e.g., map data) may have been previously downloaded or stored locally on a hard drive or optical disk. In at least one embodiment, a transmission mechanism such as data streaming in electrical or optical format can be used to transfer this content from the computer/server 720, or user database 736, to a client device 702 or another server 780, among other such options. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for performing graphical rendering operations. In other embodiments, such a system can be used for other purposes, such as for providing image or video content to test or validate autonomous machine applications, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

### Data Center

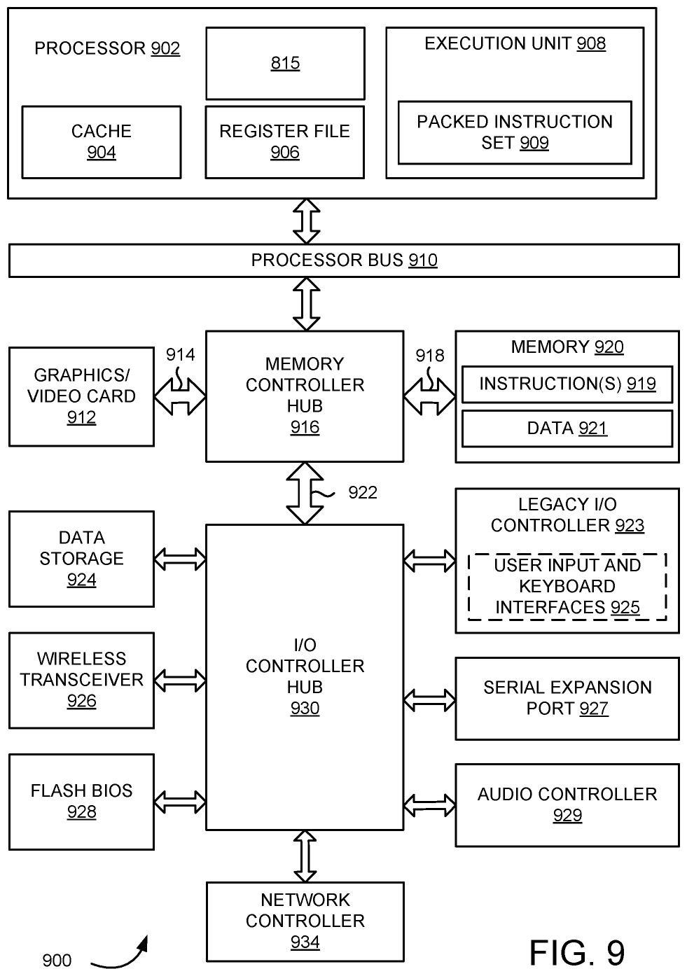

FIG. 8 illustrates an example data center 800, in which at least one embodiment may be used. In at least one embodiment, data center 800 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents a positive integer (which may be a different integer “N” than used in other figures). In at least one embodiment, node C.R.s 816(1)-816(N) may include, but are not limited to, any number of central processing units (“CPUs”) or other processors (including accelerators, field programmable gate arrays (FPGAs), graphics processors, etc.), memory storage devices 818(1)-818(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). In at least one embodiment, separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 800. In at least one embodiment, resource orchestrator 812 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may utilize distributed file system 828 for large-scale data processing (e.g., “big data”). In at least one embodiment, job scheduler 822 may include a Spark driver to facilitate scheduling of workloads supported by various layers of data center 800. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of distributed file system 828 and job scheduler 822. In at least one embodiment, clustered or grouped computing resources may include grouped computing resources 814 at data center infrastructure layer 810. In at least one embodiment, resource manager 826 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. In at least one embodiment, one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 824, resource manager 826, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underutilized and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 815 are used to perform inferencing and/or training operations associated with one or more embodiments. In at least one embodiment, inference and/or training logic 815 may be used in system FIG. 8 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

### Computer Systems

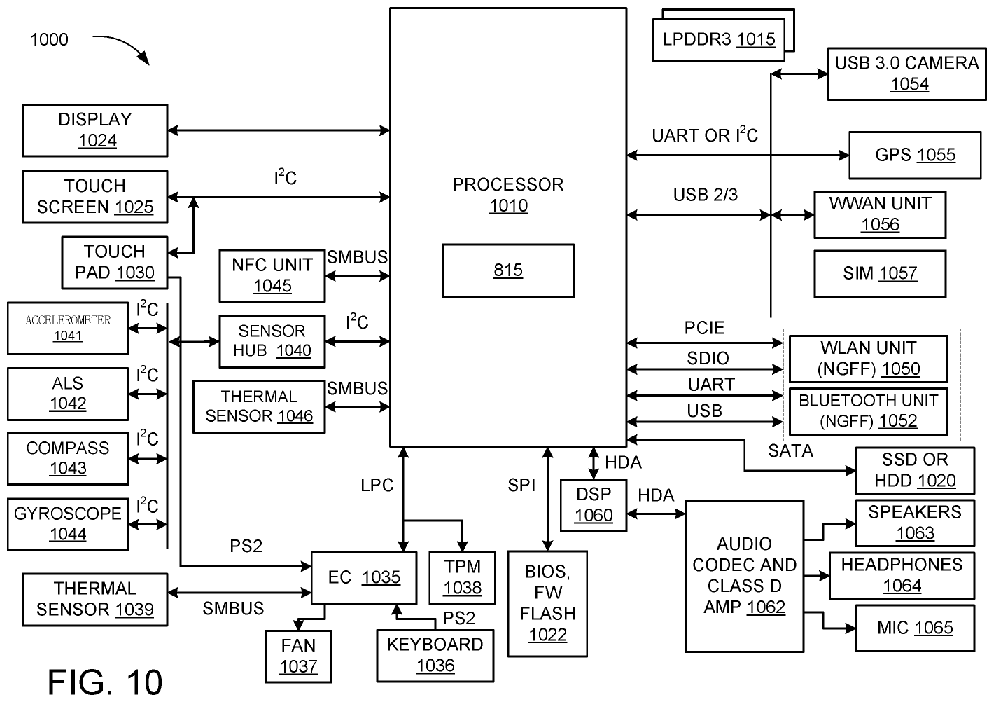

FIG. 9 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 900 may include, without limitation, a component, such as a processor 902 to employ execution units including logic to perform algorithms for process data, in accordance with present disclosure, such as in embodiment described herein. In at least one embodiment, computer system 900 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 900 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 900 may include, without limitation, processor 902 that may include, without limitation, one or more execution units 908 to perform machine learning model training and/or inferencing according to techniques described herein. In at least one embodiment, computer system 900 is a single processor desktop or server system, but in another embodiment, computer system 900 may be a multiprocessor system. In at least one embodiment, processor 902 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 902 may be coupled to a processor bus 910 that may transmit data signals between processor 902 and other components in computer system 900.

In at least one embodiment, processor 902 may include, without limitation, a Level 1 (“L1”) internal cache memory (“cache”) 904. In at least one embodiment, processor 902 may have a single internal cache or multiple levels of internal cache. In at least one embodiment, cache memory may reside external to processor 902. Other embodiments may also include a combination of both internal and external caches depending on particular implementation and needs. In at least one embodiment, a register file 906 may store different types of data in various registers including, without limitation, integer registers, floating point registers, status registers, and an instruction pointer register.

In at least one embodiment, execution unit 908, including, without limitation, logic to perform integer and floating point operations, also resides in processor 902. In at least one embodiment, processor 902 may also include a microcode (“ucode”) read only memory (“ROM”) that stores microcode for certain macro instructions. In at least one embodiment, execution unit 908 may include logic to handle a packed instruction set 909. In at least one embodiment, by including packed instruction set 909 in an instruction set of a general-purpose processor, along with associated circuitry to execute instructions, operations used by many multimedia applications may be performed using packed data in processor 902. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 908 may also be used in microcontrollers, embedded processors, graphics devices, DSPs, and other types of logic circuits. In at least one embodiment, computer system 900 may include, without limitation, a memory 920. In at least one embodiment, memory 920 may be a Dynamic Random Access Memory (“DRAM”) device, a Static Random Access Memory (“SRAM”) device, a flash memory device, or another memory device. In at least one embodiment, memory 920 may store instruction(s) 919 and/or data 921 represented by data signals that may be executed by processor 902.

In at least one embodiment, a system logic chip may be coupled to processor bus 910 and memory 920. In at least one embodiment, a system logic chip may include, without limitation, a memory controller hub (“MCH”) 916, and processor 902 may communicate with MCH 916 via processor bus 910. In at least one embodiment, MCH 916 may provide a high bandwidth memory path 918 to memory 920 for instruction and data storage and for storage of graphics commands, data, and textures. In at least one embodiment, MCH 916 may direct data signals between processor 902, memory 920, and other components in computer system 900 and to bridge data signals between processor bus 910, memory 920, and a system I/O interface 922. In at least one embodiment, a system logic chip may provide a graphics port for coupling to a graphics controller. In at least one embodiment, MCH 916 may be coupled to memory 920 through high bandwidth memory path 918 and a graphics/video card 912 may be coupled to MCH 916 through an Accelerated Graphics Port (“AGP”) interconnect 914.

In at least one embodiment, computer system 900 may use system I/O interface 922 as a proprietary hub interface bus to couple MCH 916 to an I/O controller hub (“ICH”) 930. In at least one embodiment, ICH 930 may provide direct connections to some I/O devices via a local I/O bus. In at least one embodiment, a local I/O bus may include, without limitation, a high-speed I/O bus for connecting peripherals to memory 920, a chipset, and processor 902. Examples may include, without limitation, an audio controller 929, a firmware hub (“flash BIOS”) 928, a wireless transceiver 926, a data storage 924, a legacy I/O controller 923 containing user input and keyboard interfaces 925, a serial expansion port 927, such as a Universal Serial Bus (“USB”) port, and a network controller 934. In at least one embodiment, data storage 924 may comprise a hard disk drive, a floppy disk drive, a CD-ROM device, a flash memory device, or other mass storage device.

In at least one embodiment, FIG. 9 illustrates a system, which includes interconnected hardware devices or “chips”, whereas in other embodiments, FIG. 9 may illustrate an exemplary SoC. In at least one embodiment, devices illustrated in FIG. 9 may be interconnected with proprietary interconnects, standardized interconnects (e.g., PCIe) or some combination thereof. In at least one embodiment, one or more components of computer system 900 are interconnected using compute express link (CXL) interconnects.

Inference and/or training logic 815 are used to perform inferencing and/or training operations associated with one or more embodiments. In at least one embodiment, inference and/or training logic 815 may be used in system FIG. 9 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

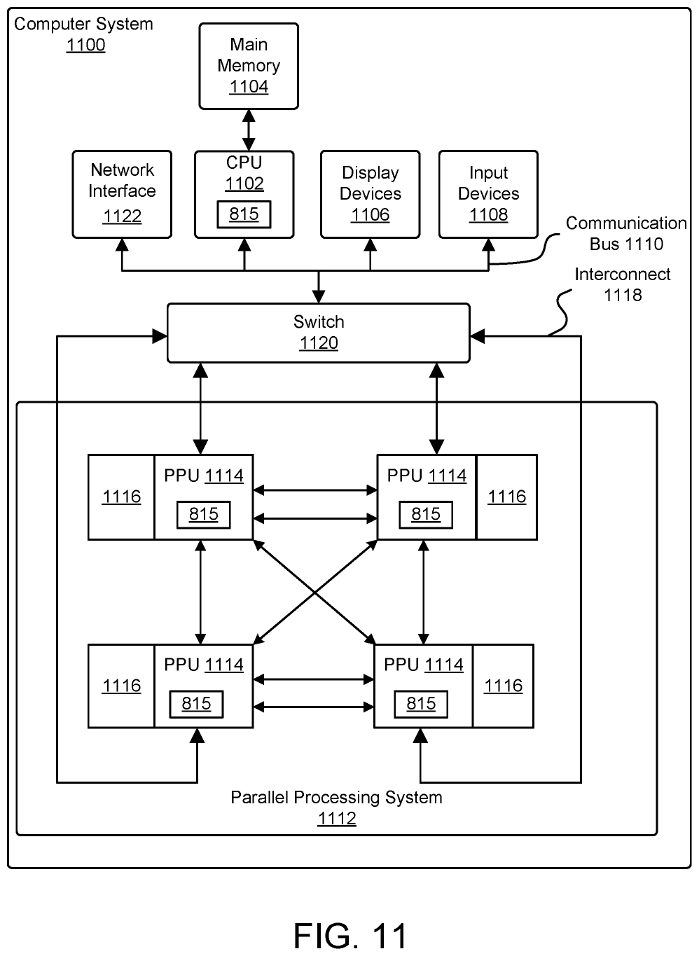

FIG. 10 is a block diagram illustrating an electronic device 1000 for utilizing a processor 1010, according to at least one embodiment. In at least one embodiment, electronic device 1000 may be, for example and without limitation, a notebook, a tower server, a rack server, a blade server, a laptop, a desktop, a tablet, a mobile device, a phone, an embedded computer, or any other suitable electronic device.

In at least one embodiment, electronic device 1000 may include, without limitation, processor 1010 communicatively coupled to any suitable number or kind of components, peripherals, modules, or devices. In at least one embodiment, processor 1010 is coupled using a bus or interface, such as a I²C bus, a System Management Bus (“SMBus”), a Low Pin Count (LPC) bus, a Serial Peripheral Interface (“SPI”), a High Definition Audio (“HDA”) bus, a Serial Advance Technology Attachment (“SATA”) bus, a Universal Serial Bus (“USB”) (versions 1, 2, 3, etc.), or a Universal Asynchronous Receiver/Transmitter (“UART”) bus. In at least one embodiment, FIG. 10 illustrates a system, which includes interconnected hardware devices or “chips”, whereas in other embodiments, FIG. 10 may illustrate an exemplary SoC. In at least one embodiment, devices illustrated in FIG. 10 may be interconnected with proprietary interconnects, standardized interconnects (e.g., PCIe) or some combination thereof. In at least one embodiment, one or more components of FIG. 10 are interconnected using compute express link (CXL) interconnects.

In at least one embodiment, FIG. 10 may include a display 1024, a touch screen 1025, a touch pad 1030, a Near Field Communications unit (“NFC”) 1045, a sensor hub 1040, a thermal sensor 1046, an Express Chipset (“EC”) 1035, a Trusted Platform Module (“TPM”) 1038, BIOS/firmware/flash memory (“BIOS, FW Flash”) 1022, a DSP 1060, a drive 1020 such as a Solid State Disk (“SSD”) or a Hard Disk Drive (“HDD”), a wireless local area network unit (“WLAN”) 1050, a Bluetooth unit 1052, a Wireless Wide Area Network unit (“WWAN”) 1056, a Global Positioning System (GPS) unit 1055, a camera (“USB 3.0 camera”) 1054 such as a USB 3.0 camera, and/or a Low Power Double Data Rate (“LPDDR”) memory unit (“LPDDR3”) 1015 implemented in, for example, an LPDDR3 standard. These components may each be implemented in any suitable manner.

In at least one embodiment, other components may be communicatively coupled to processor 1010 through components described herein. In at least one embodiment, an accelerometer 1041, an ambient light sensor (“ALS”) 1042, a compass 1043, and a gyroscope 1044 may be communicatively coupled to sensor hub 1040. In at least one embodiment, a thermal sensor 1039, a fan 1037, a keyboard 1036, and touch pad 1030 may be communicatively coupled to EC 1035. In at least one embodiment, speakers 1063, headphones 1064, and a microphone (“mic”) 1065 may be communicatively coupled to an audio unit (“audio codec and class D amp”) 1062, which may in turn be communicatively coupled to DSP 1060. In at least one embodiment, audio unit 1062 may include, for example and without limitation, an audio coder/decoder (“codec”) and a class D amplifier. In at least one embodiment, a SIM card (“SIM”) 1057 may be communicatively coupled to WWAN unit 1056. In at least one embodiment, components such as WLAN unit 1050 and Bluetooth unit 1052, as well as WWAN unit 1056 may be implemented in a Next Generation Form Factor (“NGFF”).

Inference and/or training logic 815 are used to perform inferencing and/or training operations associated with one or more embodiments. In at least one embodiment, inference and/or training logic 815 may be used in system FIG. 10 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

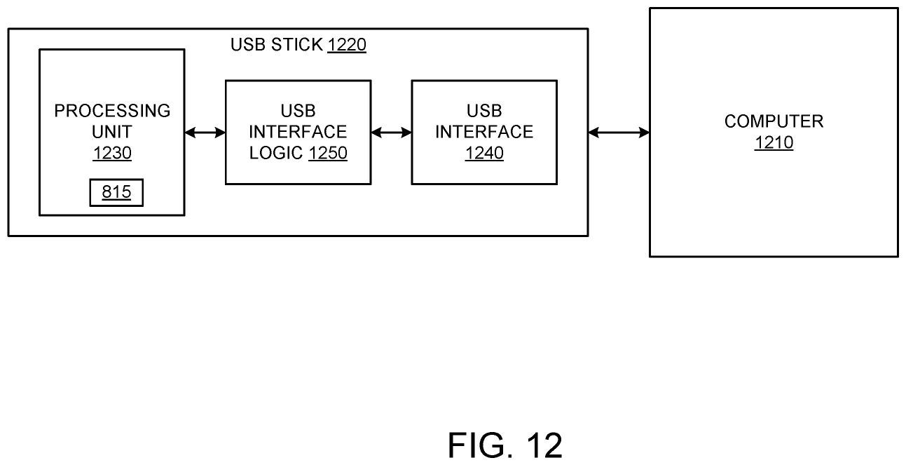

FIG. 11 illustrates a computer system 1100, according to at least one embodiment. In at least one embodiment, computer system 1100 is configured to implement various processes and methods described throughout this disclosure.

In at least one embodiment, computer system 1100 comprises, without limitation, at least one central processing unit (“CPU”) 1102 that is connected to a communication bus 1110 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1100 includes, without limitation, a main memory 1104 and control logic (e.g., implemented as hardware, software, or a combination thereof) and data are stored in main memory 1104, which may take form of random access memory (“RAM”). In at least one embodiment, a network interface subsystem (“network interface”) 1122 provides an interface to other computing devices and networks for receiving data from and transmitting data to other systems with computer system 1100.

In at least one embodiment, computer system 1100, in at least one embodiment, includes, without limitation, input devices 1108, a parallel processing system 1112, and display devices 1106 that can be implemented using a conventional cathode ray tube (“CRT”), a liquid crystal display (“LCD”), a light emitting diode (“LED”) display, a plasma display, or other suitable display technologies. In at least one embodiment, user input is received from input devices 1108 such as keyboard, mouse, touchpad, microphone, etc. In at least one embodiment, each module described herein can be situated on a single semiconductor platform to form a processing system.

Inference and/or training logic 815 are used to perform inferencing and/or training operations associated with one or more embodiments. In at least one embodiment, inference and/or training logic 815 may be used in system FIG. 11 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

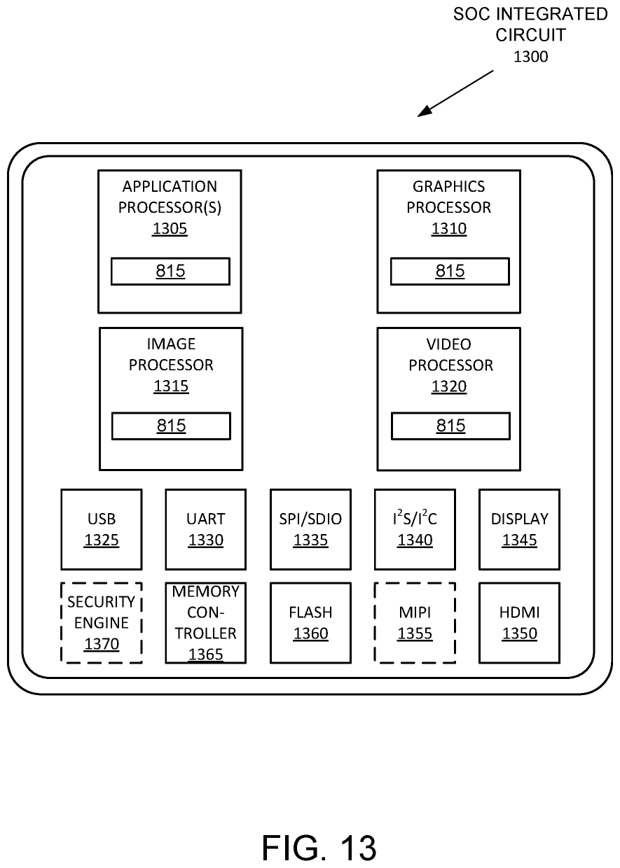

FIG. 12 illustrates a computer system 1200, according to at least one embodiment. In at least one embodiment, computer system 1200 includes, without limitation, a computer 1210 and a USB stick 1220. In at least one embodiment, computer 1210 may include, without limitation, any number and type of processor(s) (not shown) and a memory (not shown). In at least one embodiment, computer 1210 includes, without limitation, a server, a cloud instance, a laptop, and a desktop computer.

In at least one embodiment, USB stick 1220 includes, without limitation, a processing unit 1230, a USB interface 1240, and USB interface logic 1250. In at least one embodiment, processing unit 1230 may be any instruction execution system, apparatus, or device capable of executing instructions. In at least one embodiment, processing unit 1230 may include, without limitation, any number and type of processing cores (not shown). In at least one embodiment, processing unit 1230 comprises an application specific integrated circuit (“ASIC”) that is optimized to perform any amount and type of operations associated with machine learning. For instance, in at least one embodiment, processing unit 1230 is a tensor processing unit (“TPC”) that is optimized to perform machine learning inference operations. In at least one embodiment, processing unit 1230 is a vision processing unit (“VPU”) that is optimized to perform machine vision and machine learning inference operations.

In at least one embodiment, USB interface 1240 may be any type of USB connector or USB socket. For instance, in at least one embodiment, USB interface 1240 is a USB 3.0 Type-C socket for data and power. In at least one embodiment, USB interface 1240 is a USB 3.0 Type-A connector. In at least one embodiment, USB interface logic 1250 may include any amount and type of logic that enables processing unit 1230 to interface with devices (e.g., computer 1210) via USB connector 1240.

Inference and/or training logic 815 are used to perform inferencing and/or training operations associated with one or more embodiments. In at least one embodiment, inference and/or training logic 815 may be used in system FIG. 12 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

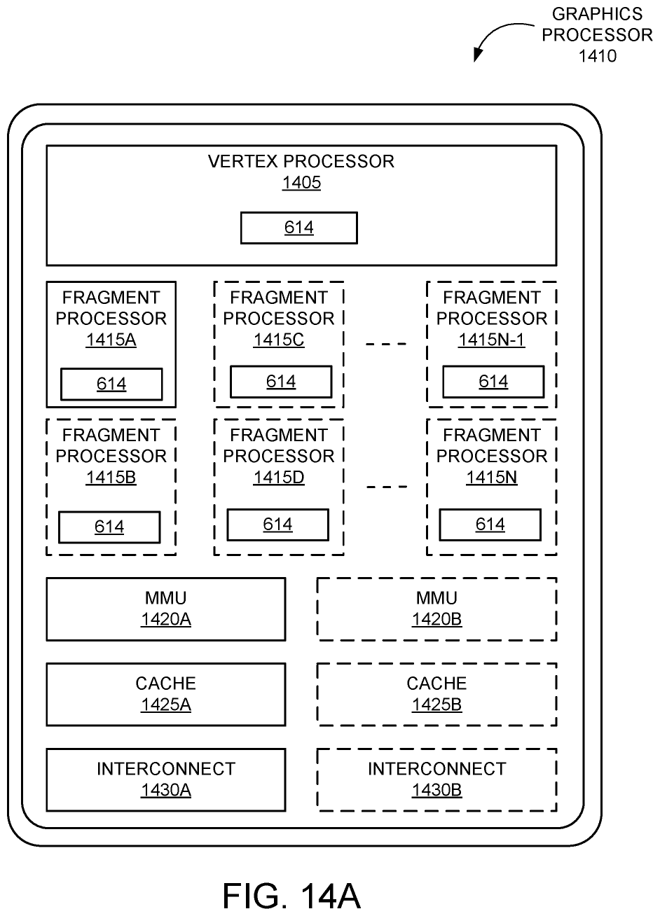

FIG. 13 illustrates exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIG. 13 is a block diagram illustrating an exemplary system-on-a-chip (SOC) integrated circuit 1300 that may be fabricated using one or more IP cores, according to at least one embodiment. In at least one embodiment, SOC integrated circuit 1300 includes one or more application processor(s) 1305 (e.g., CPUs), at least one graphics processor 1310, and may additionally include an image processor 1315 and/or a video processor 1320, any of which may be a modular IP core. In at least one embodiment, SOC integrated circuit 1300 includes peripheral or bus logic including a USB controller 1325, a UART controller 1330, an SPI/SDIO controller 1335, and an I²2S/I²2C controller 1340. In at least one embodiment, SOC integrated circuit 1300 can include a display device 1345 coupled to one or more of a high-definition multimedia interface (HDMI) controller 1350 and a mobile industry processor interface (MIPI) display interface 1355. In at least one embodiment, storage may be provided by a flash memory subsystem 1360 including flash memory and a flash memory controller. In at least one embodiment, a memory interface may be provided via a memory controller 1365 for access to SDRAM or SRAM memory devices. In at least one embodiment, some integrated circuits additionally include an embedded security engine 1370.

Inference and/or training logic 815 are used to perform inferencing and/or training operations associated with one or more embodiments. In at least one embodiment, inference and/or training logic 815 may be used in SOC integrated circuit 1300 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

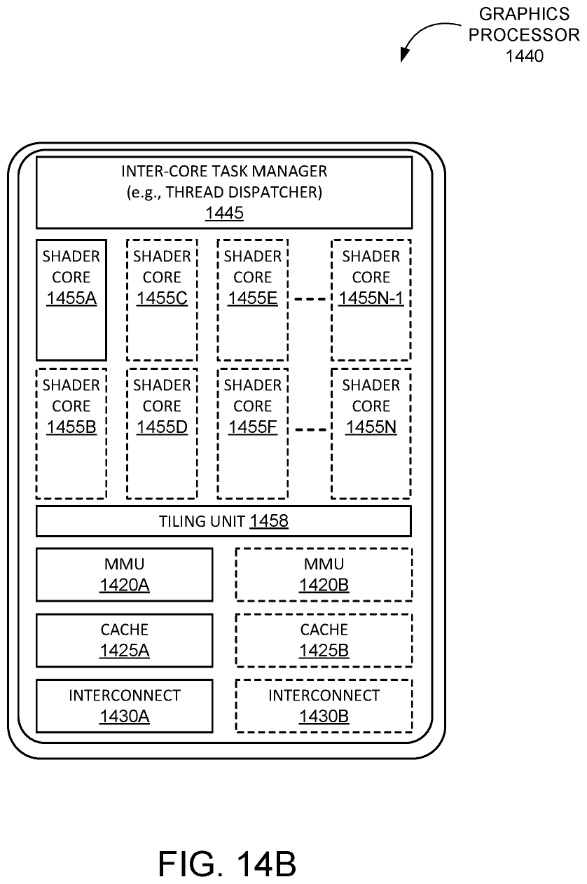

FIGS. 14A-14B illustrate exemplary integrated circuits and associated graphics processors that may be fabricated using one or more IP cores, according to various embodiments described herein. In addition to what is illustrated, other logic and circuits may be included in at least one embodiment, including additional graphics processors/cores, peripheral interface controllers, or general-purpose processor cores.

FIGS. 14A-14B are block diagrams illustrating exemplary graphics processors for use within an SoC, according to embodiments described herein. FIG. 14A illustrates an exemplary graphics processor 1410 of a system on a chip integrated circuit that may be fabricated using one or more IP cores, according to at least one embodiment. FIG. 14B illustrates an additional exemplary graphics processor 1440 of a system on a chip integrated circuit that may be fabricated using one or more IP cores, according to at least one embodiment. In at least one embodiment, graphics processor 1410 of FIG. 14A is a low power graphics processor core. In at least one embodiment, graphics processor 1440 of FIG. 14B is a higher performance graphics processor core. In at least one embodiment, each of graphics processors 1410, 1440 can be variants of computer system 1200 of FIG. 12.

In at least one embodiment, graphics processor 1410 includes a vertex processor 1405 and one or more fragment processor(s) 1415A-1415N (e.g., 1415A, 1415B, 1415C, 1415D, through 1415N-1, and 1415N). In at least one embodiment, graphics processor 1410 can execute different shader programs via separate logic, such that vertex processor 1405 is optimized to execute operations for vertex shader programs, while one or more fragment processor(s) 1415A-1415N execute fragment (e.g., pixel) shading operations for fragment or pixel shader programs. In at least one embodiment, vertex processor 1405 performs a vertex processing stage of a 3D graphics pipeline and generates primitives and vertex data. In at least one embodiment, fragment processor(s) 1415A-1415N use primitive and vertex data generated by vertex processor 1405 to produce a framebuffer that is displayed on a display device. In at least one embodiment, fragment processor(s) 1415A-1415N are optimized to execute fragment shader programs as provided for in an OpenGL API, which may be used to perform similar operations as a pixel shader program as provided for in a Direct 3D API.

In at least one embodiment, graphics processor 1410 additionally includes one or more memory management units (MMUs) 1420A-1420B, cache(s) 1425A-1425B, and circuit interconnect(s) 1430A-1430B. In at least one embodiment, one or more MMU(s) 1420A-1420B provide for virtual to physical address mapping for graphics processor 1410, including for vertex processor 1405 and/or fragment processor(s) 1415A-1415N, which may reference vertex or image/texture data stored in memory, in addition to vertex or image/texture data stored in one or more cache(s) 1425A-1425B. In at least one embodiment, one or more MMU(s) 1420A-1420B may be synchronized with other MMUs within a system, including one or more MMUs associated with one or more application processor(s) 1405, image processors 1415, and/or video processors 1420 of FIG. 14A, such that each processor 1405-1420 can participate in a shared or unified virtual memory system. In at least one embodiment, one or more circuit interconnect(s) 1430A-1430B enable graphics processor 1410 to interface with other IP cores within SoC, either via an internal bus of SoC or via a direct connection.

In at least one embodiment, graphics processor 1440 includes one or more shader core(s) 1455A-1455N (e.g., 1455A, 1455B, 1455C, 1455D, 1455E, 1455F, through 1455N-1, and 1455N) as shown in FIG. 14B, which provides for a unified shader core architecture in which a single core or type or core can execute all types of programmable shader code, including shader program code to implement vertex shaders, fragment shaders, and/or compute shaders. In at least one embodiment, a number of shader cores can vary. In at least one embodiment, graphics processor 1440 includes an inter-core task manager 1445, which acts as a thread dispatcher to dispatch execution threads to one or more shader cores 1455A-1455N and a tiling unit 1458 to accelerate tiling operations for tile-based rendering, in which rendering operations for a scene are subdivided in image space, for example to exploit local spatial coherence within a scene or to optimize use of internal caches.

Embodiments presented herein can provide for the reduction in impedance differences between components of a data transmission system.

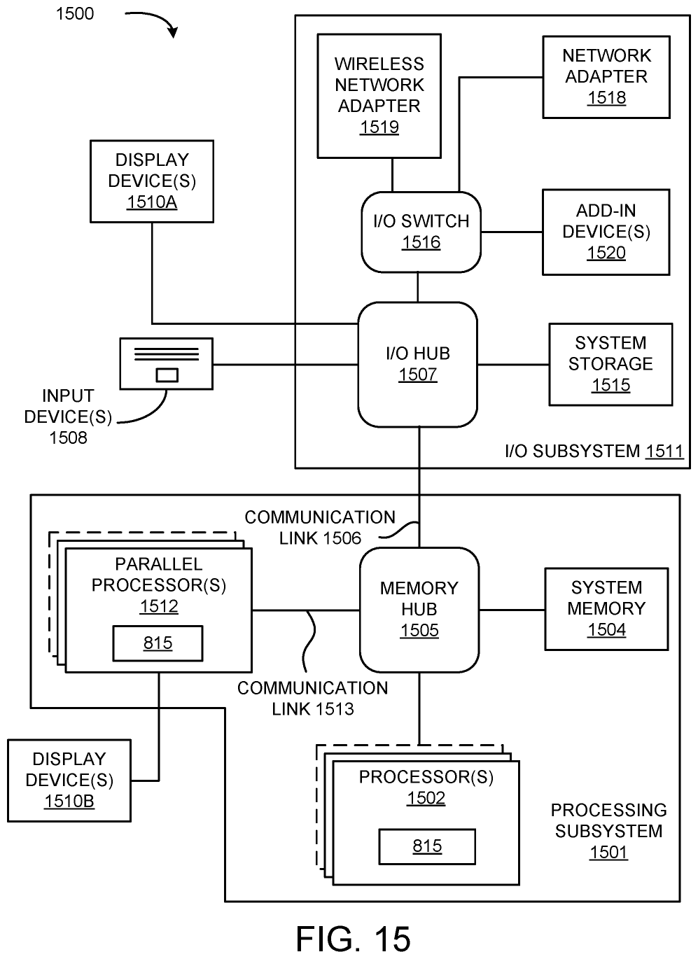

FIG. 15 is a block diagram illustrating a computing system 1500 according to at least one embodiment. In at least one embodiment, computing system 1500 includes a processing subsystem 1501 having one or more processor(s) 1502 and a system memory 1504 communicating via an interconnection path that may include a memory hub 1505. In at least one embodiment, memory hub 1505 may be a separate component within a chipset component or may be integrated within one or more processor(s) 1502. In at least one embodiment, memory hub 1505 couples with an I/O subsystem 1511 via a communication link 1506. In at least one embodiment, I/O subsystem 1511 includes an I/O hub 1507 that can enable computing system 1500 to receive input from one or more input device(s) 1508. In at least one embodiment, I/O hub 1507 can enable a display controller, which may be included in one or more processor(s) 1502, to provide outputs to one or more display device(s) 1510A. In at least one embodiment, one or more display device(s) 1510A coupled with I/O hub 1507 can include a local, internal, or embedded display device.

In at least one embodiment, processing subsystem 1501 includes one or more parallel processor(s) 1512 coupled to memory hub 1505 via a bus or other communication link 1513. In at least one embodiment, communication link 1513 may use one of any number of standards based communication link technologies or protocols, such as but not limited to PCI Express, or may be a vendor-specific communications interface or communications fabric. In at least one embodiment, one or more parallel processor(s) 1512 form a computationally focused parallel or vector processing system that can include a large number of processing cores and/or processing clusters, such as a many-integrated core (MIC) processor. In at least one embodiment, some or all of parallel processor(s) 1512 form a graphics processing subsystem that can output pixels to one of one or more display device(s) 1510A coupled via I/O hub 1507. In at least one embodiment, parallel processor(s) 1512 can also include a display controller and display interface (not shown) to enable a direct connection to one or more display device(s) 1510B. In at least one embodiment, parallel processor(s) 1512 include one or more cores, such as graphics cores 1500 discussed herein.

In at least one embodiment, a system storage unit 1514 can connect to I/O hub 1507 to provide a storage mechanism for computing system 1500. In at least one embodiment, an I/O switch 1516 can be used to provide an interface mechanism to enable connections between I/O hub 1507 and other components, such as a network adapter 1518 and/or a wireless network adapter 1519 that may be integrated into platform, and various other devices that can be added via one or more add-in device(s) 1520. In at least one embodiment, network adapter 1518 can be an Ethernet adapter or another wired network adapter. In at least one embodiment, wireless network adapter 1519 can include one or more of a Wi-Fi, Bluetooth, near field communication (NFC), or other network device that includes one or more wireless radios.

In at least one embodiment, computing system 1500 can include other components not explicitly shown, including USB or other port connections, optical storage drives, video capture devices, and like, may also be connected to I/O hub 1507. In at least one embodiment, communication paths interconnecting various components in FIG. 15 may be implemented using any suitable protocols, such as PCI (Peripheral Component Interconnect) based protocols (e.g., PCI-Express), or other bus or point-to-point communication interfaces and/or protocol(s), such as NV-Link high-speed interconnect, or interconnect protocols.

In at least one embodiment, parallel processor(s) 1512 incorporate circuitry optimized for graphics and video processing, including, for example, video output circuitry, and constitutes a graphics processing unit (GPU), e.g., parallel processor(s) 1512 includes graphics core 1500. In at least one embodiment, parallel processor(s) 1512 incorporate circuitry optimized for general purpose processing. In at least embodiment, components of computing system 1500 may be integrated with one or more other system elements on a single integrated circuit. For example, in at least one embodiment, parallel processor(s) 1512, memory hub 1505, processor(s) 1502, and I/O hub 1507 can be integrated into a system on chip (SoC) integrated circuit. In at least one embodiment, components of computing system 1500 can be integrated into a single package to form a system in package (SIP) configuration. In at least one embodiment, at least a portion of components of computing system 1500 can be integrated into a multi-chip module (MCM), which can be interconnected with other multi-chip modules into a modular computing system.

Inference and/or training logic 815 are used to perform inferencing and/or training operations associated with one or more embodiments. In at least one embodiment, inference and/or training logic 815 may be used in system FIG. 15 for inferencing or predicting operations based, at least in part, on weight parameters calculated using neural network training operations, neural network functions and/or architectures, or neural network use cases described herein.

Embodiments presented herein can provide for the reduction in impedance differences between components of a data transmission system.

### Processors

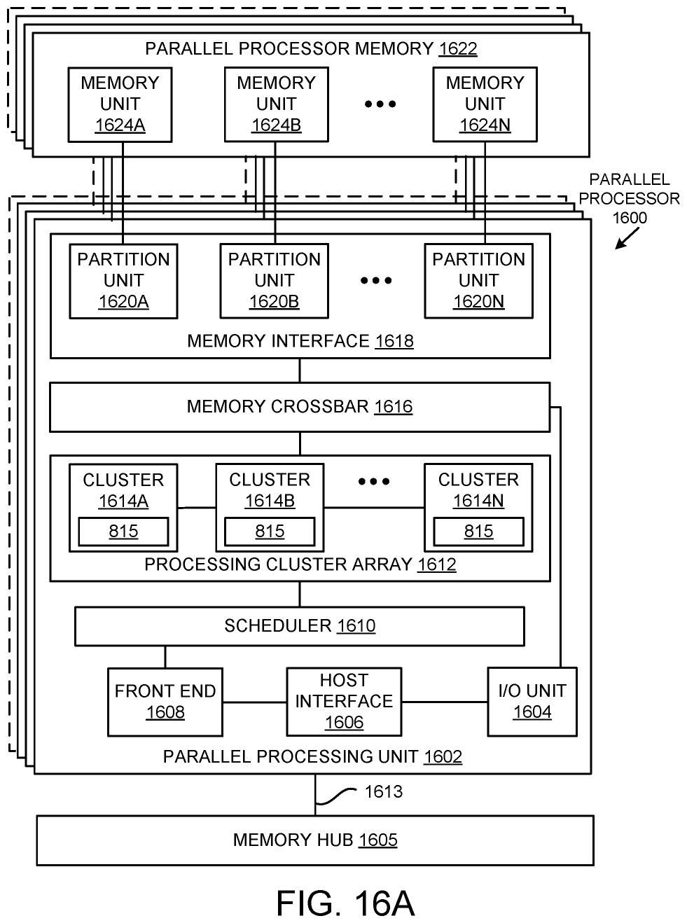

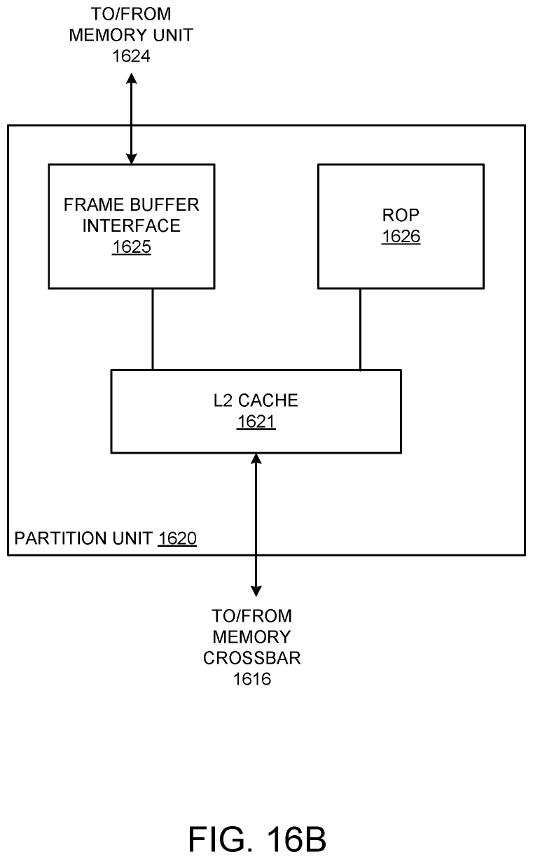

FIG. 16A illustrates a parallel processor 1600 according to at least one embodiment. In at least one embodiment, various components of parallel processor 1600 may be implemented using one or more integrated circuit devices, such as programmable processors, application specific integrated circuits (ASICs), or field programmable gate arrays (FPGA). In at least one embodiment, illustrated parallel processor 1600 is a variant of one or more parallel processor(s) 1512 shown in FIG. 15 according to an exemplary embodiment. In at least one embodiment, a parallel processor 1600 includes one or more graphics cores 1500.

In at least one embodiment, parallel processor 1600 includes a parallel processing unit 1602. In at least one embodiment, parallel processing unit 1602 includes an I/O unit 1604 that enables communication with other devices, including other instances of parallel processing unit 1602. In at least one embodiment, I/O unit 1604 may be directly connected to other devices. In at least one embodiment, I/O unit 1604 connects with other devices via use of a hub or switch interface, such as a memory hub 1605. In at least one embodiment, connections between memory hub 1605 and I/O unit 1604 form a communication link 1613. In at least one embodiment, I/O unit 1604 connects with a host interface 1606 and a memory crossbar 1616, where host interface 1606 receives commands directed to performing processing operations and memory crossbar 1616 receives commands directed to performing memory operations.

In at least one embodiment, when host interface 1606 receives a command buffer via I/O unit 1604, host interface 1606 can direct work operations to perform those commands to a front end 1608. In at least one embodiment, front end 1608 couples with a scheduler 1610 (which may be referred to as a sequencer), which is configured to distribute commands or other work items to a processing cluster array 1612. In at least one embodiment, scheduler 1610 ensures that processing cluster array 1612 is properly configured and in a valid state before tasks are distributed to a cluster of processing cluster array 1612. In at least one embodiment, scheduler 1610 is implemented via firmware logic executing on a microcontroller. In at least one embodiment, microcontroller implemented scheduler 1610 is configurable to perform complex scheduling and work distribution operations at coarse and fine granularity, enabling rapid preemption and context switching of threads executing on processing array 1612. In at least one embodiment, host software can prove workloads for scheduling on processing cluster array 1612 via one of multiple graphics processing paths. In at least one embodiment, workloads can then be automatically distributed across processing array cluster 1612 by scheduler 1610 logic within a microcontroller including scheduler 1610.

In at least one embodiment, processing cluster array 1612 can include up to “N” processing clusters (e.g., cluster 1614A, cluster 1614B, through cluster 1614N), where “N” represents a positive integer (which may be a different integer “N” than used in other figures). In at least one embodiment, each cluster 1614A-1614N of processing cluster array 1612 can execute a large number of concurrent threads. In at least one embodiment, scheduler 1610 can allocate work to clusters 1614A-1614N of processing cluster array 1612 using various scheduling and/or work distribution algorithms, which may vary depending on workload arising for each type of program or computation. In at least one embodiment, scheduling can be handled dynamically by scheduler 1610, or can be assisted in part by compiler logic during compilation of program logic configured for execution by processing cluster array 1612. In at least one embodiment, different clusters 1614A-1614N of processing cluster array 1612 can be allocated for processing different types of programs or for performing different types of computations.

In at least one embodiment, processing cluster array 1612 can be configured to perform various types of parallel processing operations. In at least one embodiment, processing cluster array 1612 is configured to perform general-purpose parallel compute operations. For example, in at least one embodiment, processing cluster array 1612 can include logic to execute processing tasks including filtering of video and/or audio data, performing modeling operations, including physics operations, and performing data transformations.

In at least one embodiment, processing cluster array 1612 is configured to perform parallel graphics processing operations. In at least one embodiment, processing cluster array 1612 can include additional logic to support execution of such graphics processing operations, including but not limited to, texture sampling logic to perform texture operations, as well as tessellation logic and other vertex processing logic. In at least one embodiment, processing cluster array 1612 can be configured to execute graphics processing related shader programs such as but not limited to, vertex shaders, tessellation shaders, geometry shaders, and pixel shaders. In at least one embodiment, parallel processing unit 1602 can transfer data from system memory via I/O unit 1604 for processing. In at least one embodiment, during processing, transferred data can be stored to on-chip memory (e.g., parallel processor memory 1622) during processing, then written back to system memory.

In at least one embodiment, when parallel processing unit 1602 is used to perform graphics processing, scheduler 1610 can be configured to divide a processing workload into approximately equal sized tasks, to better enable distribution of graphics processing operations to multiple clusters 1614A-1614N of processing cluster array 1612. In at least one embodiment, portions of processing cluster array 1612 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 1614A-1614N may be stored in buffers to allow intermediate data to be transmitted between clusters 1614A-1614N for further processing.

In at least one embodiment, processing cluster array 1612 can receive processing tasks to be executed via scheduler 1610, which receives commands defining processing tasks from front end 1608. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 1610 may be configured to fetch indices corresponding to tasks or may receive indices from front end 1608. In at least one embodiment, front end 1608 can be configured to ensure processing cluster array 1612 is configured to a valid state before a workload specified by incoming command buffers (e.g., batch-buffers, push buffers, etc.) is initiated.

In at least one embodiment, each of one or more instances of parallel processing unit 1602 can couple with a parallel processor memory 1622. In at least one embodiment, parallel processor memory 1622 can be accessed via memory crossbar 1616, which can receive memory requests from processing cluster array 1612 as well as I/O unit 1604. In at least one embodiment, memory crossbar 1616 can access parallel processor memory 1622 via a memory interface 1618. In at least one embodiment, memory interface 1618 can include multiple partition units (e.g., partition unit 1620A, partition unit 1620B, through partition unit 1620N) that can each couple to a portion (e.g., memory unit) of parallel processor memory 1622. In at least one embodiment, a number of partition units 1620A-1620N is configured to be equal to a number of memory units, such that a first partition unit 1620A has a corresponding first memory unit 1624A, a second partition unit 1620B has a corresponding memory unit 1624B, and an N-th partition unit 1620N has a corresponding N-th memory unit 1624N. In at least one embodiment, a number of partition units 1620A-1620N may not be equal to a number of memory units.

In at least one embodiment, memory units 1624A-1624N can include various types of memory devices, including dynamic random access memory (DRAM) or graphics random access memory, such as synchronous graphics random access memory (SGRAM), including graphics double data rate (GDDR) memory. In at least one embodiment, memory units 1624A-1624N may also include 3D stacked memory, including but not limited to high bandwidth memory (HBM), HBM2e, or HDM3. In at least one embodiment, render targets, such as frame buffers or texture maps may be stored across memory units 1624A-1624N, allowing partition units 1620A-1620N to write portions of each render target in parallel to efficiently use available bandwidth of parallel processor memory 1622. In at least one embodiment, a local instance of parallel processor memory 1622 may be excluded in favor of a unified memory design that utilizes system memory in conjunction with local cache memory.

In at least one embodiment, any one of clusters 1614A-1614N of processing cluster array 1612 can process data that will be written to any of memory units 1624A-1624N within parallel processor memory 1622. In at least one embodiment, memory crossbar 1616 can be configured to transfer an output of each cluster 1614A-1614N to any partition unit 1620A-1620N or to another cluster 1614A-1614N, which can perform additional processing operations on an output. In at least one embodiment, each cluster 1614A-1614N can communicate with memory interface 1618 through memory crossbar 1616 to read from or write to various external memory devices. In at least one embodiment, memory crossbar 1616 has a connection to memory interface 1618 to communicate with I/O unit 1604, as well as a connection to a local instance of parallel processor memory 1622, enabling processing units within different processing clusters 1614A-1614N to communicate with system memory or other memory that is not local to parallel processing unit 1602. In at least one embodiment, memory crossbar 1616 can use virtual channels to separate traffic streams between clusters 1614A-1614N and partition units 1620A-1620N.

In at least one embodiment, multiple instances of parallel processing unit 1602 can be provided on a single add-in card, or multiple add-in cards can be interconnected. In at least one embodiment, different instances of parallel processing unit 1602 can be configured to interoperate even if different instances have different numbers of processing cores, different amounts of local parallel processor memory, and/or other configuration differences. For example, in at least one embodiment, some instances of parallel processing unit 1602 can include higher precision floating point units relative to other instances. In at least one embodiment, systems incorporating one or more instances of parallel processing unit 1602 or parallel processor 1600 can be implemented in a variety of configurations and form factors, including but not limited to desktop, laptop, or handheld personal computers, servers, workstations, game consoles, and/or embedded systems.

FIG. 16B is a block diagram of a partition unit 1620 according to at least one embodiment. In at least one embodiment, partition unit 1620 is an instance of one of partition units 1620A-1620N of FIG. 16A. In at least one embodiment, partition unit 1620 includes an L2 cache 1621, a frame buffer interface 1625, and a ROP 1626 (raster operations unit). In at least one embodiment, L2 cache 1621 is a read/write cache that is configured to perform load and store operations received from memory crossbar 1616 and ROP 1626. In at least one embodiment, read misses and urgent write-back requests are output by L2 cache 1621 to frame buffer interface 1625 for processing. In at least one embodiment, updates can also be sent to a frame buffer via frame buffer interface 1625 for processing. In at least one embodiment, frame buffer interface 1625 interfaces with one of memory units in parallel processor memory, such as memory units 1624A-1624N of FIG. 16A (e.g., within parallel processor memory 1622).

In at least one embodiment, ROP 1626 is a processing unit that performs raster operations such as stencil, z test, blending, etc. In at least one embodiment, ROP 1626 then outputs processed graphics data that is stored in graphics memory. In at least one embodiment, ROP 1626 includes compression logic to compress depth or color data that is written to memory and decompress depth or color data that is read from memory. In at least one embodiment, compression logic can be lossless compression logic that makes use of one or more of multiple compression algorithms. In at least one embodiment, a type of compression that is performed by ROP 1626 can vary based on statistical characteristics of data to be compressed. For example, in at least one embodiment, delta color compression is performed on depth and color data on a per-tile basis.

In at least one embodiment, ROP 1626 is included within each processing cluster (e.g., cluster 1614A-1614N of FIG. 16A) instead of within partition unit 1620. In at least one embodiment, read and write requests for pixel data are transmitted over memory crossbar 1616 instead of pixel fragment data. In at least one embodiment, processed graphics data may be displayed on a display device, such as one of one or more display device(s) 1510 of FIG. 15, routed for further processing by processor(s) 1602, or routed for further processing by one of processing entities within parallel processor 1600 of FIG. 16A.

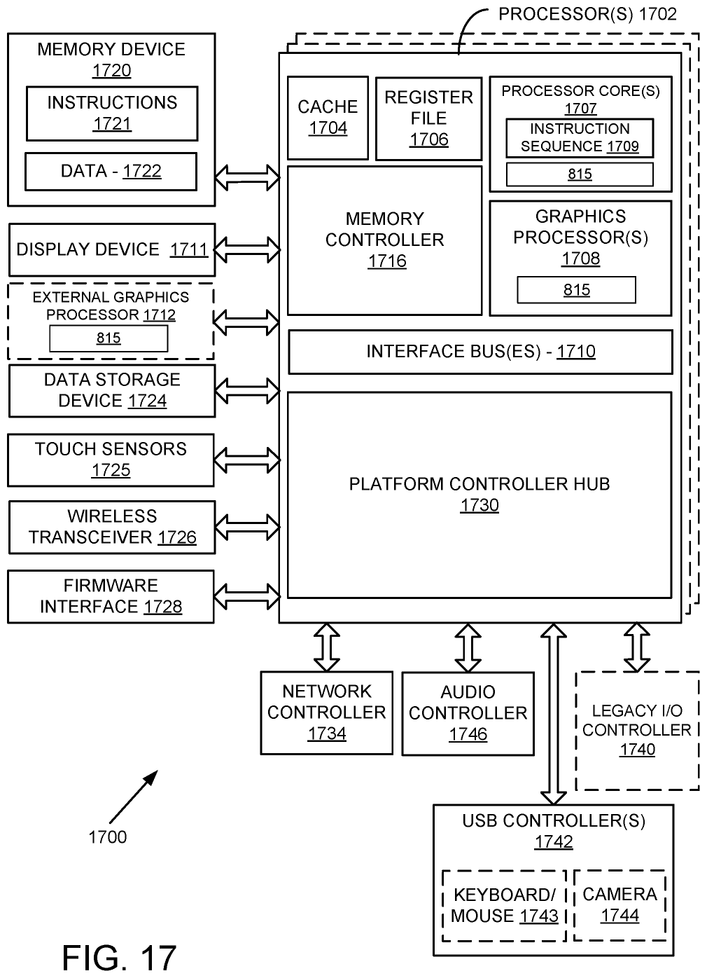

FIG. 17 is a block diagram of a processing system, according to at least one embodiment. In at least one embodiment, system 1700 includes one or more processor(s) 1702 and one or more graphics processor(s) 1708, and may be a single processor desktop system, a multiprocessor workstation system, or a server system having a large number of processor(s) 1702 or processor core(s) 1707. In at least one embodiment, system 1700 is a processing platform incorporated within a system-on-a-chip (SoC) integrated circuit for use in mobile, handheld, or embedded devices. In at least one embodiment, one or more graphics processor(s) 1708 include one or more graphics cores 1500.

In at least one embodiment, system 1700 can include, or be incorporated within a server-based gaming platform, a game console, including a game and media console, a mobile gaming console, a handheld game console, or an online game console. In at least one embodiment, system 1700 is a mobile phone, a smart phone, a tablet computing device or a mobile Internet device. In at least one embodiment, processing system 1700 can also include, couple with, or be integrated within a wearable device, such as a smart watch wearable device, a smart eyewear device, an augmented reality device, or a virtual reality device. In at least one embodiment, processing system 1700 is a television or set top box device having one or more processor(s) 1702 and a graphical interface generated by one or more graphics processor(s) 1708.

In at least one embodiment, one or more processor(s) 1702 each include one or more processor core(s) 1707 to process instructions which, when executed, perform operations for system and user software. In at least one embodiment, each of one or more processor core(s) 1707 is configured to process a specific instruction sequence 1709. In at least one embodiment, instruction sequence 1709 may facilitate Complex Instruction Set Computing (CISC), Reduced Instruction Set Computing (RISC), or computing via a Very Long Instruction Word (VLIW). In at least one embodiment, processor core(s) 1707 may each process a different instruction sequence 1709, which may include instructions to facilitate emulation of other instruction sequences. In at least one embodiment, processor core(s) 1707 may also include other processing devices, such a Digital Signal Processor (DSP).

In at least one embodiment, processor(s) 1702 includes a cache memory 1704. In at least one embodiment, processor(s) 1702 can have a single internal cache or multiple levels of internal cache. In at least one embodiment, cache memory is shared among various components of processor(s) 1702. In at least one embodiment, processor(s) 1702 also uses an external cache (e.g., a Level-3 (L3) cache or Last Level Cache (LLC)) (not shown), which may be shared among processor core(s) 1707 using known cache coherency techniques. In at least one embodiment, a register file 1706 is additionally included in processor(s) 1702, which may include different types of registers for storing different types of data (e.g., integer registers, floating point registers, status registers, and an instruction pointer register). In at least one embodiment, register file 1706 may include general-purpose registers or other registers.

In at least one embodiment, one or more processor(s) 1702 are coupled with one or more interface bus(es) 1710 to transmit communication signals such as address, data, or control signals between processor(s) 1702 and other components in system 1700. In at least one embodiment, interface bus(es) 1710 can be a processor bus, such as a version of a Direct Media Interface (DMI) bus. In at least one embodiment, interface bus(es) 1710 is not limited to a DMI bus, and may include one or more Peripheral Component Interconnect buses (e.g., PCI, PCI Express), memory busses, or other types of interface busses. In at least one embodiment processor(s) 1702 include an integrated memory controller 1716 and a platform controller hub 1730. In at least one embodiment, memory controller 1716 facilitates communication between a memory device and other components of system 1700, while platform controller hub (PCH) 1730 provides connections to I/O devices via a local I/O bus.

In at least one embodiment, a memory device 1720 can be a dynamic random access memory (DRAM) device, a static random access memory (SRAM) device, flash memory device, phase-change memory device, or some other memory device having suitable performance to serve as process memory. In at least one embodiment, memory device 1720 can operate as system memory for system 1700, to store data 1722 and instructions 1721 for use when one or more processor(s) 1702 executes an application or process. In at least one embodiment, memory controller 1716 also couples with an optional external graphics processor 1712, which may communicate with one or more graphics processor(s) 1708 in processor(s) 1702 to perform graphics and media operations. In at least one embodiment, a display device 1711 can connect to processor(s) 1702. In at least one embodiment, display device 1711 can include one or more of an internal display device, as in a mobile electronic device or a laptop device, or an external display device attached via a display interface (e.g., DisplayPort, etc.). In at least one embodiment, display device 1711 can include a head mounted display (HMD) such as a stereoscopic display device for use in virtual reality (VR) applications or augmented reality (AR) applications.

In at least one embodiment, platform controller hub 1730 enables peripherals to connect to memory device 1720 and processor(s) 1702 via a high-speed I/O bus. In at least one embodiment, I/O peripherals include, but are not limited to, an audio controller 1746, a network controller 1734, a firmware interface 1728, a wireless transceiver 1726, touch sensors 1725, a data storage device 1724 (e.g., hard disk drive, flash memory, etc.). In at least one embodiment, data storage device 1724 can connect via a storage interface (e.g., SATA) or via a peripheral bus, such as a Peripheral Component Interconnect bus (e.g., PCI, PCI Express). In at least one embodiment, touch sensors 1725 can include touch screen sensors, pressure sensors, or fingerprint sensors. In at least one embodiment, wireless transceiver 1726 can be a Wi-Fi transceiver, a Bluetooth transceiver, or a mobile network transceiver such as a 3G, 4G, or Long Term Evolution (LTE) transceiver. In at least one embodiment, firmware interface 1728 enables communication with system firmware, and can be, for example, a unified extensible firmware interface (UEFI). In at least one embodiment, network controller 1734 can enable a network connection to a wired network. In at least one embodiment, a high-performance network controller (not shown) couples with interface bus(es) 1710. In at least one embodiment, audio controller 1746 is a multi-channel high definition audio controller. In at least one embodiment, system 1700 includes an optional legacy I/O controller 1740 for coupling legacy (e.g., Personal System 2 (PS/2)) devices to system 1700. In at least one embodiment, platform controller hub 1730 can also connect to one or more Universal Serial Bus (USB) controller(s) 1742 connect input devices, such as keyboard and mouse 1743 combinations, a camera 1744, or other USB input devices.

In at least one embodiment, an instance of memory controller 1716 and platform controller hub 1730 may be integrated into a discreet external graphics processor, such as external graphics processor 1712. In at least one embodiment, platform controller hub 1730 and/or memory controller 1716 may be external to one or more processor(s) 1702. For example, in at least one embodiment, system 1700 can include an external memory controller 1716 and platform controller hub 1730, which may be configured as a memory controller hub and peripheral controller hub within a system chipset that is in communication with processor(s) 1702.

Embodiments presented herein can provide for the reduction in impedance differences between components of a data transmission system.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. An electro-absorption modulated laser (EML) device, comprising:
an input line for receiving an electrical signal from a signal source;
a continuous wave laser;
an electro-absorption modulator (EAM) to modulate light from the continuous wave laser according to the electrical signal received to the input line; and
an electrical filter positioned at the input line and including one or more components to reduce a difference in impedance between the signal source and the EAM device.

2. The electro-absorption modulated laser device of claim 1, wherein the electrical filter is a resistor-capacitor (RC) filter including at least one resistor and at least one capacitor connected in parallel.

3. The electro-absorption modulated laser device of claim 1, wherein the continuous wave laser and the EAM are positioned on a semiconductor chip, and wherein the electrical filter is monolithically integrated on the chip, or comprised of discrete components on a chip carrier supporting the semiconductor chip.

4. The electro-absorption modulated laser device of claim 1, wherein the EAM is a single-ended modulator, or a differential modulator optionally including a second electrical filter.

5. The electro-absorption modulated laser device of claim 4, wherein the EAM is a single ended input modulator manufactured on an n-type semiconductor substrate, or a differential input modulator manufactured on a semi-insulating substrate.

6. The electro-absorption modulated laser device of claim 1, wherein capacitances supported by the electrical filter are in the range of 100-350 fF, wherein resistances supported by the electrical filter are in the range of 5-20 ohms, and wherein a characteristic frequency of the electrical filters is in the range of 50-150 GHz.

7. The electro-absorption modulated laser device of claim 1, wherein the electrical filter includes one or more thin metal layers or dielectric layers in common with a manufacturing process of the EAM.

8. The electro-absorption modulated laser device of claim 1, wherein the electrical filter has a characteristic frequency with reduced attenuations at frequencies above a threshold frequency, and with the characteristic filter frequency being of the same order of magnitude as the bandwidth of the EAM of the EML.

9. The electro-absorption modulated laser device of claim 1, wherein the input signal from the signal source is a radio frequency (RF) electrical input.

10. The electro-absorption modulated laser device of claim 1, wherein the EAM is one of a lumped element single ended driven device, a traveling wave single ended driven device, a lumped element differentially driven device, or a traveling wave differentially driven device.

11. The electro-absorption modulated laser device of claim 1, wherein electrical filter is selected to reduce an electrical reflection return loss, increase a bandwidth, or flatten a frequency response of EML device.

12. A method, comprising:
receiving, to an input line of an electro-absorption modulated laser (EML) device, an electrical signal from an electrical signal source;
using at least one electrical filter, in the EML device, to reduce a difference in impedance between the signal source and a modulator of the EML device; and
modulating light, from a laser of the EML, using an electro-absorption modulator (EAM) of the EML according to the electrical signal from the signal source.

13. The method of claim 12, wherein the electrical filter is a resistor-capacitor (RC) filter including at least one resistor and at least one capacitor connected in parallel.

14. The method of claim 12, wherein the laser and the EAM are positioned on a semiconductor chip, and wherein the electrical filter is monolithically integrated on the chip, or comprised of discrete components on a chip carrier supporting the semiconductor chip.

15. The method of claim 12, wherein the EAM is a single-ended modulator, or a differential modulator optionally including a second electrical filter.

16. A data transmission device, comprising an input line for receiving an electric signal and an electro-absorption modulated laser (EML) for transmitting an optical signal modulated according to the electric signal, the data transmission device further comprising an electrical filter, at the input line, having a reduced attenuation at frequencies above a frequency threshold, and a characteristic filter frequency of a same order of magnitude as a bandwidth of the data transmission device.

17. The data transmission device of claim 16, wherein the modulator is an electro-absorption modulator (EAM) comprised within the data transmission device.

18. The data transmission device of claim 16, wherein the electrical filter is a resistor-capacitor (RC) filter including at least one resistor and at least one capacitor connected in parallel.

19. The data transmission device of claim 16, wherein the laser and the EAM are positioned on a semiconductor chip, and wherein the electrical filter is monolithically integrated on the chip, or comprised of discrete components on a chip carrier supporting the semiconductor chip.

20. The data transmission device of claim 16, wherein the data transmission device is comprised in at least one of:
a system for performing simulation operations;
a system for performing simulation operations to test or validate autonomous machine applications;
a system for performing digital twin operations;
a system for performing light transport simulation;
a system for rendering graphical output;
a system for performing deep learning operations;
a system for performing generative AI operations using a large language model (LLM);
a system implemented using an edge device;
a system for generating or presenting virtual reality (VR) content;
a system for generating or presenting augmented reality (AR) content;
a system for generating or presenting mixed reality (MR) content;
a system incorporating one or more Virtual Machines (VMs);
a system implemented at least partially in a data center;
a system for performing hardware testing using simulation;
a system for performing generative operations using a language model (LM);
a system for synthetic data generation;
a collaborative content creation platform for 3D assets; or
a system implemented at least partially using cloud computing resources.
